(19) United States
(12) Patent Application Publication
(10) Pub. No.: US 2007/0235841 A1
(43) Pub. Date: Oct. 11, 2007

(54) Silicon nanowire structure and method for making same

(75) Inventors: Shuai-ping Ge, Beijing (CN); Kai-Li Jiang, Beijing (CN); Shou-Shan Fan, Beijing (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignees: Tsinghua University, Beijing City (CN); HON HAI Precision Industry CO., LTD., Tu-Cheng City (TW)

(21) Appl. No.: 11/214,379

(22) Filed: Aug. 29, 2005

(30) Foreign Application Priority Data
Aug. 28, 2004 (CN) 200410051311.7

(51) Int. Cl. H01L 29/04

(52) U.S. Cl. 257/627; 977/762; 977/763

(57) ABSTRACT

A silicon nanowire structure with controllable orientations is disclosed. The silicon nanowire structure includes a silicon wafer as a substrate having a crystal plane; a plurality of silicon nanowires extends from the silicon wafer along a plurality of oblique epitaxial <111> directions of the substrate. The silicon nanowires are in a form of single crystalline nanowires. The crystal plane can be one of a (100) crystal plane, a (110) crystal plane, and a (111) crystal plane. A method for growing the silicon nanowire structure is also disclosed. The silicon nanowire structures have potential applications in nanoscale photonics and/or electronic devices. The method uses a silicon wafer having a crystal plane as a substrate. By controlling a local concentration of silicon derived from SiCl₄ vapor at the reaction zone, silicon nanowires with controlled orientations can be grown from the silicon wafer.

### BACKGROUND OF THE INVENTION

1. Field of the Invention

The present invention relates to silicon nanowires and methods for synthesizing them, and more particularly to a silicon nanowire array having controllable orientations and a method for synthesizing such an array.

2. Related Art

In the modem integrated circuit (IC) industry, an important theme of development is smaller and faster ICs with less power consumption. However, as the IC industry gradually evolves from a micro-electronics age to a nano-electronics age, conventional semiconductor manufacture technologies are considered likely to reach their limits. Such technologies notably include lithographic techniques (the so-called “top-down” approach), and such techniques may be found wanting in the future. An alternative solution may be the “bottom-up” approach (also called the self-assembly approach). In recent years, the “bottom-up” approach has yielded various nano-scaled structures, including different kinds of nanotubes and nanowires (so-called one-dimensional nano-materials). Owing to their unique structures and properties, the nano-scaled structures have shown many promising potential applications in nano-scaled electronics, photonics, sensors and superlattices. Silicon is one of the most favored materials in the semiconductor industry, and it has been used in the IC industry for many years. Therefore, silicon nanowires (SiNWs) are generally preferred over other nanowires in terms of technical compatibility. Accordingly, much attention has already been paid to the research and synthesis of silicon nanowires. As early as in 1964, Wagner et al. successfully synthesized micrometer-scaled silicon whiskers grown on silicon substrates (see Applied Physics Letters, 1964, vol. 4, p.89). Nowadays, many methods are known for synthesizing silicon nanowires, including CCVD (catalytic chemical vapor deposition), laser evaporation, direct thermal evaporation, template-directed synthesis, etc. However, most of these conventional methods have the disadvantages of producing only curled nanowires with a relative short length, and the nanowires having much impurity.

A conventional method for producing silicon nanowires has been proposed. The method includes steps of activating a vapor phase silicon monoxide or suboxide (i.e., SiₓO where x≧1) carried in an inert gas, and growing silicon nanowires from the activated vapor phase silicon monoxide or suboxide on a substrate maintained at a temperature ranging from 800 to 1000 degrees Celsius. However, the silicon nanowires grown by this method have random orientations with respect to the substrate. This disadvantage restricts the range of applications available for the silicon nanowires. In addition, this method produces a number of impurities. That is, a number of unwanted silicon nanoparticles having random orientations are produced, and these form a number of silicon nanoparticle chains.

Yiying Wu et al. discloses a method for growing single-crystalline Si/SiGe superlattice nanowires, in an article entitled “Block-by-Block Growth of Single-Crystalline Si/SiGe Superlattice Nanowires” (Nano Letters, Vol. 2, No. 2, p. 83-86, 2002). The method employs a substrate comprising a (111) silicon wafer coated with a thin layer of Au. The substrate is put inside a quartz tube furnace. A gas mixture containing H₂ and SiCl₄ is continuously introduced into the furnace. Germanium (Ge) vapor is generated in a pulsed form by pulsed ablation of a pure Ge target with a Nd:YAG laser. In this way, single-crystalline nanowires with a Si/SiGe superlattice structure are obtained.

The above article discloses a method for the synthesis of a semiconductor nanowire with periodic longitudinal heterostructures containing silicon sections and SiGe sections. However, the single-crystalline nanowires according to the above method have only one orientation; i.e., a direction perpendicular to the (111) silicon substrate. These silicon nanowires with Si/SiGe superlattices having the characteristics of only one orientation may have potential applications such as in light emitting devices. However, the method cannot be applied to produce silicon nanowire networks or other patterns, which are critical or even essential for the creation of various nano-scaled planar or three-dimensional functional structures. In addition, according to the article, the method is applied only to the (111) silicon wafer with the thin layer of Au.

Accordingly, what is needed is a method for manufacturing silicon nanowires with controlled orientations, and for manufacturing silicon nanowire arrays having controllable orientations with respect to a substrate.

### SUMMARY

An embodiment of the present invention provides a silicon nanowire structure with controllable orientations. The silicon nanowire structure comprises a substrate including a silicon wafer having a crystal plane, and a plurality of silicon nanowires extending from the substrate along a plurality of oblique epitaxial <111> directions of the substrate. The silicon nanowires are in a single crystalline form.

Preferably, the crystal plane is a (100) crystal plane, and the silicon nanowires form an angle of 35.3 degrees with respect to the (100) crystal plane.

The crystal plane can be a (110) crystal plane, and the silicon nanowires form an angle of 54.7 degrees with respect to the (110) crystal plane.

The crystal plane can be a (111) crystal plane, and accordingly the silicon nanowires form an angle of 19.4 degrees with respect to the (111) crystal plane. In addition, the silicon nanowires can grow perpendicular to the (111) crystal plane.

Another embodiment of the present invention provides a method for manufacturing a silicon nanowire structure, the method comprising:
providing a substrate comprising a silicon wafer having a crystal plane;
forming a catalyst layer on the crystal plane of the silicon substrate;
placing the silicon substrate with the catalyst layer formed thereon into a reaction device;
introducing a gas mixture comprising a silicon-containing gas and a carrier gas into the reaction device for reaction at a temperature of approximately 500 to 1100 degrees Celsius, wherein a molar ratio of silicon of the silicon-containing gas to the carrier gas is in the range from 0.05 to 0.4, and preferably 0.05˜0.2;
depositing silicon decomposed from the silicon-containing gas on an inner sidewall of the reaction device until an equilibrium is reached; and
growing silicon nanowires from the crystal plane of the silicon substrate along an epitaxial <111> direction.

The crystal plane comprises a (100) crystal plane, a (110) crystal plane, and a (111) crystal plane. The carrier gas comprises hydrogen gas.

The catalyst layer comprises a thin layer of a catalyst having a thickness less than 50 nanometers. Alternatively, the catalyst layer comprises a plurality of nanoparticles of a catalyst, with a diameter of the nanoparticles being less than 300 nanometers. The catalyst can be gold or iron. The silicon-containing material comprises a silicon halide, a silane and any derivative thereof, and halogenated silanes.

Other systems, methods, features, and advantages will be or become apparent to one skilled in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

FIG. 1A is a SEM (scanning electron microscope) view of a silicon nanowire structure grown on a (100) silicon substrate according to a preferred embodiment of the present invention;

FIG. 1B is another SEM view of a silicon nanowire structure grown on a (100) silicon substrate according to the preferred embodiment of the present invention;

FIG. 1C is an HRTEM (high resolution transmission electron microscope) view of a silicon nanowire structure grown on a (100) silicon substrate according to the preferred embodiment of the present invention;

FIG. 1D is a schematic, isometric view of a silicon nanowire's four growth directions on a (100) silicon substrate according to the preferred embodiment of the present invention;

FIG. 2A is a SEM view of a silicon nanowire structure grown on a (110) silicon substrate according to the preferred embodiment of the present invention;

FIG. 2B is another SEM view of a silicon nanowire structure grown on a (110) silicon substrate according to the preferred embodiment of the present invention;

FIG. 2C is an HRTEM view of a silicon nanowire structure grown on a (110) silicon substrate according to the preferred embodiment of the present invention;

FIG. 2D is a schematic, isometric view of a silicon nanowire's two growth directions on a (110) silicon substrate according to the preferred embodiment of the present invention;

FIG. 3A is a SEM view of a silicon nanowire structure grown on a (111) silicon substrate according to the preferred embodiment of the present invention;

FIG. 3B is another SEM view of a silicon nanowire structure grown on a (111) silicon substrate according to the preferred embodiment of the present invention;

FIG. 3C is still another SEM view of a silicon nanowire structure grown on a (111) silicon substrate according to the preferred embodiment of the present invention;

FIG. 3D is an HRTEM view of a silicon nanowire structure grown on a (111) silicon substrate according to the preferred embodiment of the present invention;

FIG. 3E is a schematic, isometric view of a silicon nanowire's four growth directions on a (111) silicon substrate according to the preferred embodiment of the present invention; and

FIG. 4 is a simplified, schematic side view of an apparatus for growing silicon nanowires according to the preferred embodiment of the present invention.

### DETAILED DESCRIPTION OF THE PREFERRED EMBODIMENTS

Reference will now be made to the drawings to describe preferred embodiments of the present invention in detail.

According to a preferred embodiment of the present invention, self-oriented silicon nanowires can be produced by epitaxial growth on a crystalline substrate. By controlling growth conditions, controllable epitaxial growth of nanowires is realized. Therefore, mass synthesis of nanowires with controllable orientations and structure is attained, which facilitates the construction of functional nanowire devices with desired different patterns or configurations.

Substrates for growth of nanowires used in the preferred embodiments can be one of a (100) silicon wafer, a (110) silicon wafer, and a (111) silicon wafer. The (100) silicon wafer, (110) silicon wafer and (111) silicon wafer have a (100) crystal plane, a (110) crystal plane and a (111) crystal plane respectively, i.e., a surface with predefined crystal orientation. The corresponding crystal planes are used as epitaxial growth surfaces.

Prior to synthesis of silicon nanowires, the above three kinds of silicon wafers are prepared, and a catalyst thin film having a thickness on the order of nanometers is deposited on the corresponding crystal planes respectively. The catalyst thin film is preferred made of gold (Au). However, the catalyst thin film is not necessarily limited to gold, and other catalyst thin films such as one made of iron (Fe) may also be employed. The thickness of the catalyst thin film affects a diameter of silicon nanowires subsequently produced. That is, the thicker the catalyst thin film, the greater the diameter of the silicon nanowires, and vice versa. Generally, the thickness of the catalyst thin film may be in the range of several nanometers to 50 nanometers. Alternatively, a plurality of catalyst particles having diameters less than 300 nanometers may be sprinkled on the crystal planes, instead of the deposition of the catalyst thin film.

In the preferred embodiment, three large-sized silicon wafers including a (100) silicon wafer, a (110) silicon wafer, and a (111) silicon wafer coated with a gold thin film as a catalyst are first provided. Each of the large-sized silicon wafers is cut into three small pieces, each approximately 10 mm×10 mm in size. Each of the pieces is designated with a number, as shown in table 1.

TABLE 1
Number of Silicon Wafer Pieces

| Run | (100) silicon wafer | (110) silicon wafer | (111) silicon wafer |
|---|---|---|---|
| 1 | 11^{#} | 12^{#} | 13^{#} |
| 2 | 21^{#} | 22^{#} | 23^{#} |
| 3 | 31^{#} | 32^{#} | 33^{#} |

In order to facilitate comparison, the preferred embodiment includes three growth runs. In each growth run, as shown in table 1, three different small pieces of silicon wafer are used for growth of silicon nanowires.

Referring initially to FIG. 4, a reaction apparatus 10 for growth of silicon nanowires includes a furnace 100, a quartz tube 110 having a gas inlet 112 and a gas outlet 114 at two ends thereof, and a bubbler 120 filled with a liquid comprised of SiCl₄. The quartz tube 110 is movably arranged inside the furnace 100. However, the quartz tube 110 is longer than the furnace 100, so that at least a portion of the quartz tube 110 remains inside the furnace 100 when the quartz tube 110 is pushed inward or pulled outward. The bubbler 120 is preferably held in an isothermal bath (not shown) at a temperature of 30 degrees Celsius. An output (not labeled) of the bubbler 120 is connected with the quartz tube 110 near the gas inlet 112 of the quartz tube 110. In addition, a gas pipe 122 for introducing a carrier gas is connected with the bubbler 120. An end of the gas pipe 122 is immersed into the SiCl₄ liquid. Thus when the carrier gas is introduced into the bubbler 120, a vapor of the SiC₄ is carried into the quartz tube 110 for reaction. A holder for holding the substrates (i.e., the small pieces of silicon wafer previously prepared) is placed inside the quartz tube 110. The holder may be, for example, a ceramic boat 116.

It is noted that the SiCl₄ liquid is used as a source of silicon. Other sources of silicon may be used instead of SiCl₄ liquid. For example, a liquid comprised of derivatives of a silane, a silicon halide, halogenated silanes, etc. may be used.

The furnace 100 is heated to a reaction temperature in the range from 500 to 1100 degrees Celsius. For instance, the furnace 100 is heated to 900 degrees Celsius. Because the quartz tube 110 is longer than the furnace 100, a part (not labeled) of the quartz tube 110 inside the furnace 100 is heated to the reaction temperature, while other parts of the quartz tube 110 outside the furnace 100 remained at a relatively low temperature. The parts of the quartz tube 110 at the low temperature can be called cold parts (not labeled). Thus, a first growth run is started, and includes the following steps:
First, three small pieces of silicon wafer 118 (only one is shown in FIG. 4) are placed on the ceramic boat 116, and the ceramic boat 116 is placed in a cold part of the quartz tube 110. The three small pieces of silicon wafer 118 include the 11# (100) silicon wafer, the 12# (110) silicon wafer, and the 13# (111) silicon wafer (see table 1). A protecting gas, such as pure argon gas, is introduced into the quartz tube 110 at a flow rate of 350 sccm (standard cube centimeters per minute) from the inlet 112. This process expels air out from the quartz tube 110, and is continued for a period of time such as, for example, 20 minutes.
After the air is eliminated from the quartz tube 110, the quartz tube 110 is pushed so as to move the ceramic boat 116 and the silicon wafers 118 to a central heating area of the furnace 100. Preferably, in order to maintain the temperature of the furnace as constant as possible, the quartz tube 110 is pushed slowly. This can keep the change of the temperature of the furnace 100 to less than 10 degrees Celsius.
When the temperature has returned to and stabilized at the reaction temperature (i.e., 900 degrees Celsius in the described embodiment), the argon gas flowing through the inlet 112 is replaced with hydrogen gas moving at a flow rate of 250 sccm. In addition, hydrogen gas as a carrier gas is introduced into the bubbler 120 via the gas pipe 122 at a flow rate of 100 sccm, thereby carrying a vapor comprising of SiCl₄ into the quartz tube 110 for reaction. The reaction lasts for a period of time such as, for example, 10 minutes. It is understood that the longer the reaction time lasts, the longer the silicon nanowires produced.
The hydrogen gas flowing through the inlet 112 is replaced with argon gas moving at a flow rate of 350 sccm. The quartz tube 110 is moved so as to locate the ceramic boat 116 and the silicon wafers 118 outside of the furnace 100, thereby enabling cooling of the silicon wafers 118. The furnace 100 maintains its temperature, and other parts of the quartz tube 110 remain inside the furnace 100.
After the silicon wafers 118 are cooled down to room temperature, the silicon wafers 118 are taken out from the ceramic boat 116. Thus, the first growth run is finished.

In the present embodiments, the carrier gas is not necessarily limited to the flow rates mentioned above. The flow rate of the carrier gas may be varied, so long as the carrier gas can carry enough SiCl₄ vapor into the quartz tube 110 for reaction. Preferably, a molar ratio of the carried SiCl₄ to the carrier gas (i.e., hydrogen) is in the range from 0.05 to 0.4; and more preferably, in the range from 0.05 to 0.2. It is understood that an amount of SiCl₄ vapor carried into the quartz tube 110 for reaction can be adjusted by control of the amount of the carrier gas and the temperature of the SiCl₄ vapor (i.e., the temperature of the isothermal bath). It is noted that, since a SiCl₄ molecule contains only one silicon atom, the molar ratio of the SiCl₄ to hydrogen equal to ratio of silicon to hydrogen; if an other material containing more than one silicon atom in a molecule is used instead of the SiCl₄, the flow rate of the material may be changed according to the number of silicon atoms in the molecule of the material.

During the first growth run, a silicon layer (not shown) is deposited on an inner sidewall of the quartz tube 110. Without cleaning the silicon layer from the quartz tube 110, a second growth run is begun. Three small pieces of silicon wafers including the 21# (100) silicon wafer, the 22# (110) silicon wafer, and the 23# (111) silicon wafer are placed on the ceramic boat 116. The ceramic boat 116 is placed in the cold part of the quartz tube 110. By following the relevant steps for the first growth run described above, the second growth run is completed. After that, without cleaning the silicon layer from the quartz tube 110, a third growth run is begun. Three small pieces of silicon wafers, i.e., the 31# (100) silicon wafer, the 32# (110) silicon wafer, and the 33# (111) silicon wafer, are used for the third growth run. The same steps as for the first or second growth runs are followed.

In the above-described embodiment, the first growth run results in silicon nanowires formed on the 13# (111) silicon wafer only. No silicon nanowires are found on the 114 (100) silicon wafer or the 12# (110) silicon wafer. However, in the second growth run and the third growth run, silicon nanowires are formed on all of the silicon wafers, including the 21# (100) silicon wafer, the 22# (110) silicon wafer, and the 23# (111) silicon wafer of the second growth run, and the 31# (100) silicon wafer, the 32# (110) silicon wafer, and the 33# (111) silicon wafer of the third growth run. The silicon nanowires have a length of from approximately 10 micrometers to several tens micrometers, and a diameter of from approximately 50 nanometers to 250 nanometers.

The silicon nanowires grown on the different silicon wafers will be discussed in detailed below respectively.

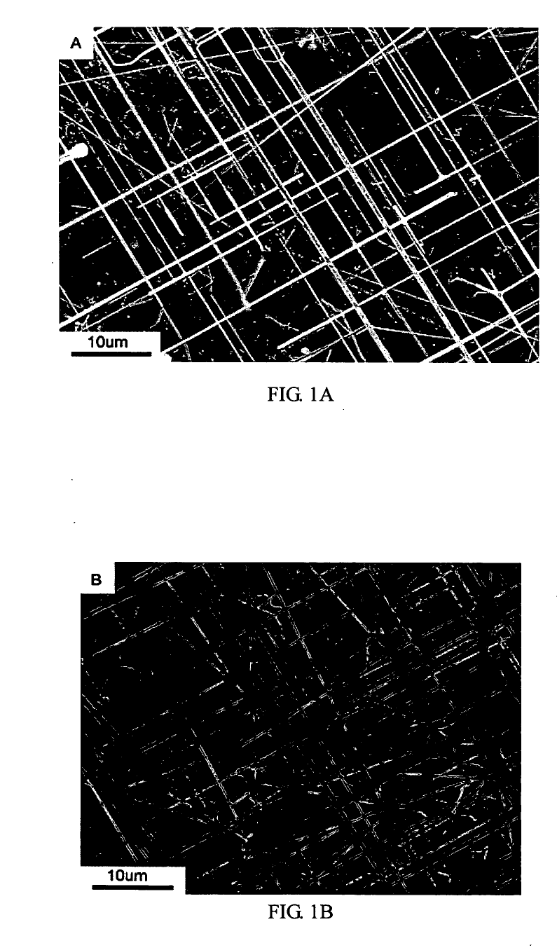

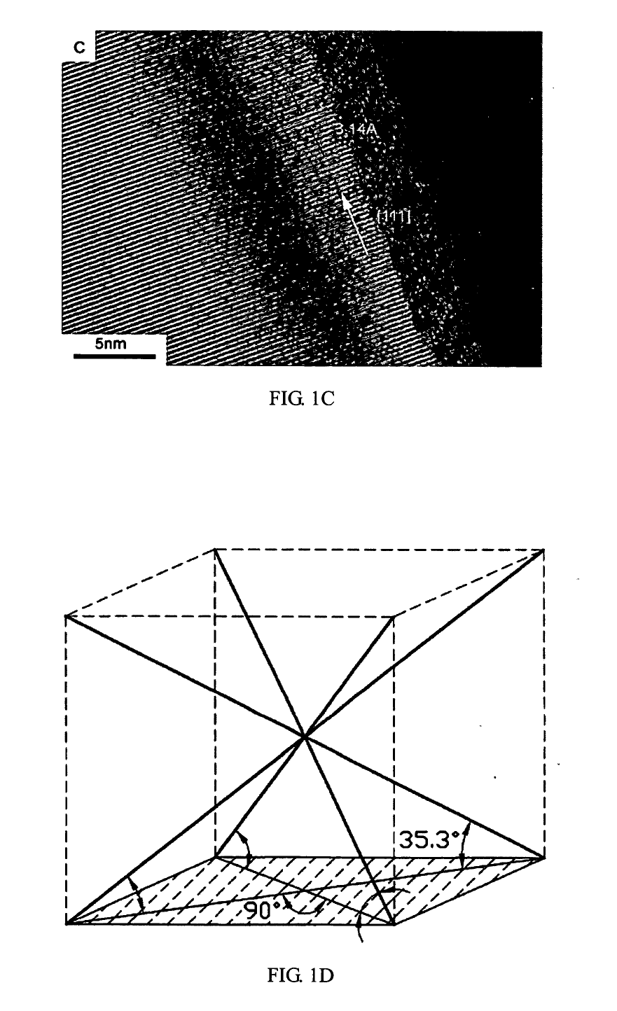

Referring to FIGS. 1A and 1B, these are SEM views taken from tops of the silicon nanowires grown on the 21# and 31# (100) silicon wafers in the second growth run and the third growth run, respectively. The scale bars are 10 micrometers long. The silicon nanowires appear to be in the form of rectangular networks. Actually, if the sample stage is inclined for further observation, it is found that the silicon nanowires have grown along four directions, with each direction defining an angle of approximately 35 degrees with respect to the silicon wafers. The rectangular networks viewed in FIGS. 1A and 1B are orthographic projections of the four directions. The four directions are four epitaxial <111> directions of the (100) silicon wafer, each defining an angle of 35.3 degrees with respect to the surface of the (100) silicon wafer. This is confirmed by HRTEM analysis. Referring to FIG 1C, an HRTEM view of the silicon nanowires grown on one of the 21# and 31# (100) silicon wafers is shown. The scale bar is 5 nanometers long. Referring to FIG 1D, the four epitaxial <111> directions of the (100) silicon wafer are shown. In particular, a hatched surface represents the (100) crystal plane, and four crossed continuous solid lines each forming an angle of 35.3 degrees with respect to the (100) crystal plane represent the four epitaxial <111> directions. The silicon nanowires grown on the 21# and 31# (100) silicon wafers in the second growth run and the third growth run extend along the four epitaxial <111> directions.

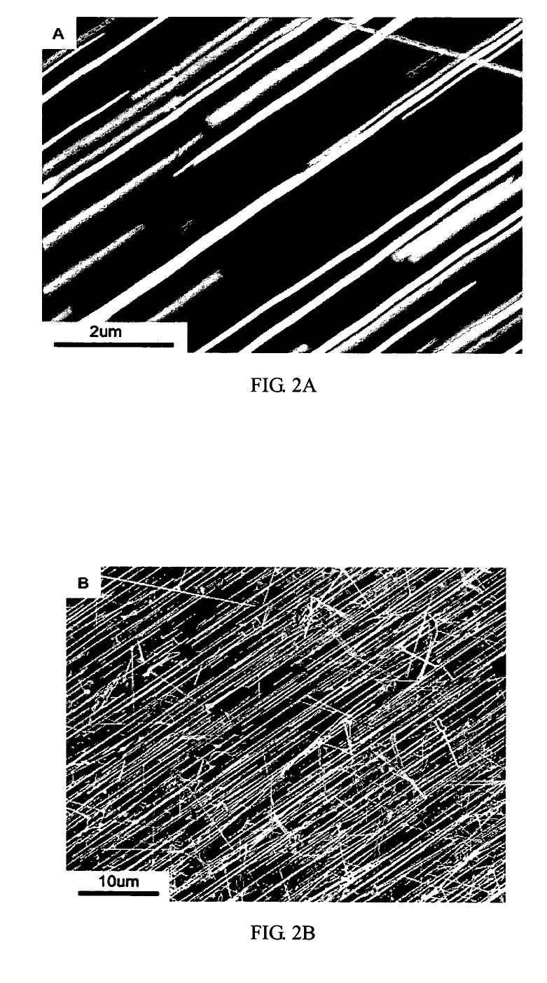

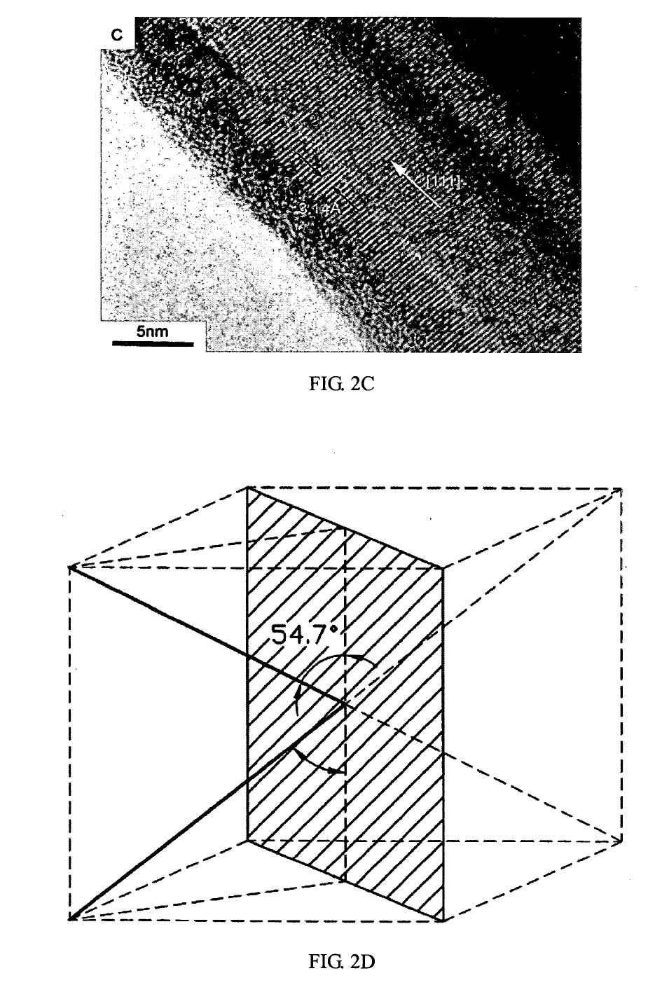

Referring to FIGS. 2A and 2B, these are SEM views taken from tops of the silicon nanowires grown on the 22# and 32# (110) silicon wafers in the second growth run and the third growth run, respectively. The scale bars are respectively 2 micrometers and 10 micrometers long. Most of the silicon nanowires appear to be parallel with each other. Actually, the silicon nanowires extend along two directions, each direction defining an angle of approximate 55 degrees with respect to the silicon wafer. It is the orthographic projections of the silicon nanowires on the substrate that are mutually parallel. The two directions are two epitaxial <111> directions of the (110) silicon wafer, each defining an angle of 54.7 degrees with respect to the surface of the (110) silicon wafer. This is confirmed by HRTEM analysis. Referring to FIG. 2C, an HRTEM view of the silicon nanowires grown on one of the 22# and 32# (110) silicon wafers is shown. The scale bar is 5 nanometers long. Referring to FIG. 2D, the two epitaxial <111> directions of the (110) silicon wafer are shown. A hatched surface represents the (110) crystal plane, and two crossed continuous solid lines each defining an angle of 54.7 degrees with respect to the (110) crystal plane represent the two epitaxial <111> directions. The silicon nanowires grown on the 22# and 32# (110) silicon wafers in the second growth run and the third growth run extend along the two epitaxial <111> directions.

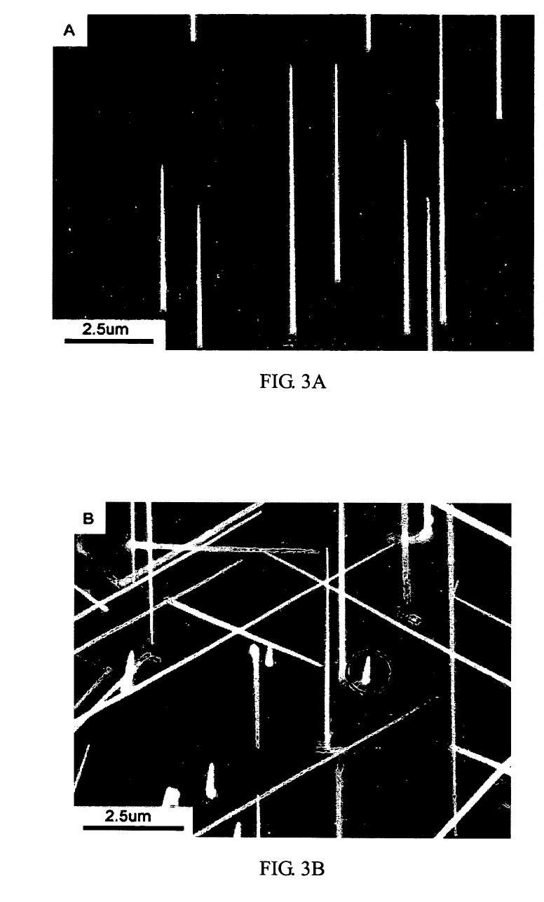

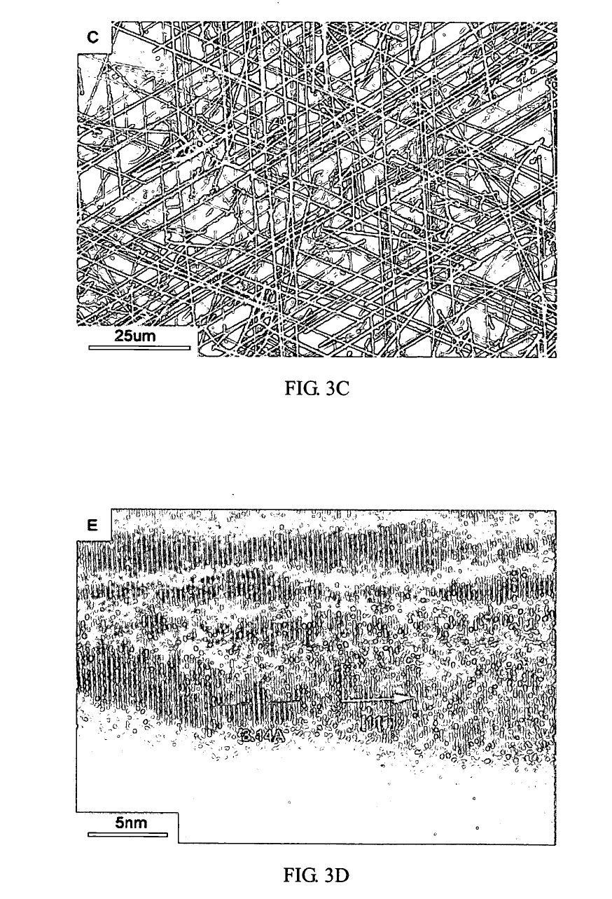

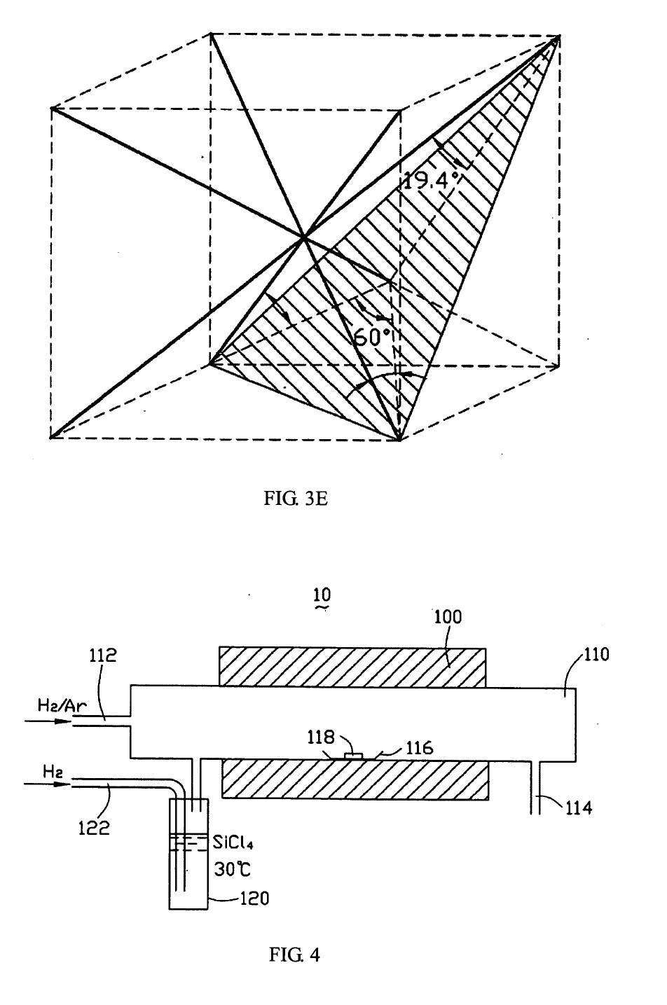

Referring to FIGS. 3A, 3B and 3C, these are SEM views of the silicon nanowires grown on the 13#, 23# and 33# (111) silicon wafers in the first, second and the third growth runs, respectively. The SEM view of FIG. 3A is taken when the sample stage is rotated an angle about 60 degrees. The SEM views of FIGS. 3B and 3C are taken vertically from tops of the samples. The scale bars are respectively 2.5 micrometers, 2.5 micrometers, and 25 micrometers long. As shown in FIG. 3A, all of the silicon nanowires obtained in the first growth run are perpendicular with the crystal plane of the silicon wafer. As shown in FIG. 3B, the silicon nanowires obtained in the second growth run form a plurality of triangular networks, with some additional highlight spots (e.g., one marked with a black circle) being distributed among the triangular networks. Detailed observations indicate that the silicon nanowires grow along four directions. One of the directions is perpendicular with respect to the silicon wafer (the highlight spot marked with a black circle represents this perpendicular direction). The others directions are inclined, each defining an angle of approximately 19 degrees with respect to the silicon wafer. In FIG. 3C, the silicon nanowires obtained in the third growth run form a plurality of triangular networks without highlight spots. That is, no silicon nanowires grow perpendicular to the silicon wafer. The four directions are four epitaxial <111> directions of the (111) silicon wafer, which is confirmed by HRTEM analysis. It is the orthographic projections of the silicon nanowires on the substrate that form the triangular networks and the highlight spots. Referring to FIG. 3D, an HRTEM view of the silicon nanowires grown on one of the 13#, 23# and 33# (111 ) silicon wafers is shown. The scale bar is 5 nanometers long. Referring to FIG. 3E, the four epitaxial <111> directions of the (111) silicon wafer are shown. A hatched surface represents the (111) crystal plane, and four crossed continuous solid lines represent the four epitaxial <111> directions of the (111) silicon wafer. One of the directions is perpendicular to the (111) crystal plane. The other three directions each define an angle of 19.4 degrees with respect to the (111) crystal plane.

As described above, even though experimental conditions (including equipment, reaction temperature, reaction gases, gas flow rates, and concentrations of the reaction gases) are kept the same, the configuration of the silicon nanowires obtained in the first growth run differs from that obtained in the second and third growth runs. The reason is that concentrations of SiCl₄ in a local reaction area are different in the three growth runs. Whether or not epitaxial growth occurs depends on a local concentration of silicon derived from the SiCl₄ vapor. The local concentration means a concentration at an actual reaction zone where chemical reaction occurs and the silicon nanowires grow. In the first growth run, because the quartz tube 110 is freshly cleaned, a portion of the silicon derived from the SiCl₄ vapor is deposited on the inner sidewall of the quartz tube 110. This results in the local concentration of silicon being relatively low. Therefore, the silicon nanowires grow only perpendicular to the silicon wafer. For the second and third growth runs, since the inner sidewall of the quartz tube 110 already has a silicon layer deposited thereon during the previous first growth run, an amount of silicon deposited on the inner sidewall gradually decreases until an equilibrium is reached. As a result, the local concentration of silicon available for reaction gradually increases to a preferred super-saturation value. Therefore, silicon nanowires grow along oblique epitaxial <111> directions.

Although the preferred embodiment includes three growth runs for comparison, the invention herein is not necessarily limited to such steps. Silicon nanowires can be grown along oblique epitaxial <111> directions so long as the local concentration of silicon reaches a preferred super-saturation value.

The above-described embodiments can control the growth directions of the silicon nanowires along oblique epitaxial <111> directions. The orientations of the silicon nanowires can be precisely controlled by the crystal orientation of the substrate. The silicon nanowires are single crystalline nanowires, and are grown along the <111> directions as confirmed by HRTEM microscopy.

The obtained silicon nanowire structures have potential applications in nanoscale photonics and/or electronic devices. For example, photonic devices can be directly implemented by patterned growth of silicon nanowires according to the embodiments without further assembling steps. In addition, it is noted that orthographic projections of the silicon nanowires on a (100) silicon wafer, a (110) silicon wafer and a (111) silicon wafer form rectangular networks, parallel straight lines, and triangular networks respectively. Thus, by directly pressing the as-synthesized silicon nanowires, planar rectangular networks, planar triangular networks or planar parallel straight line structures can be implemented. Such networks and structures can be further used in nanoelectronics.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A silicon nanowire structure, comprising:
a silicon substrate having a crystal plane; and
a plurality of silicon nanowires grown on the silicon substrate along an oblique epitaxial <111> direction of the silicon substrate.

2. The silicon nanowire structure as described in claim 1, wherein the silicon nanowires are single crystalline nanowires.

3. The silicon nanowire structure as described in claim 1, wherein the crystal plane comprises a (100) crystal plane, and the silicon nanowires define an angle of 35.3 degrees with respect to the (100) crystal plane.

4. The silicon nanowire structure as described in claim 1, wherein the crystal plane comprises a (110) crystal plane, and the silicon nanowires define an angle of 54.7 degrees with respect to the (110) crystal plane.

5. The silicon nanowire structure as described in claim 1, wherein the crystal plane comprises a (111) crystal plane, and the silicon nanowires define an angle of 19.4 degrees with respect to the (111) crystal plane.

6. The silicon nanowire structure as described in claim 5, further comprises silicon nanowires perpendicular to the (111) crystal plane.

7. The silicon nanowire structure as described in claim 1, wherein a diameter of the silicon nanowires is in the range from 50 to 250 nanometers.

8. The silicon nanowire structure as described in claim 1, wherein a length of the silicon nanowires is in the range from 10 micrometers to 90 micrometers.

9-20. (canceled)

21. A nanowire structure, comprising:
a substrate having a crystal plane; and
a plurality of nanowires grown on the substrate along an oblique epitaxial <111 > direction of the substrate.

22. The nanowire structure as described in claim 21, wherein the nanowires are single crystalline nanowires.

23. The nanowire structure as described in claim 21, wherein the crystal plane comprises a (100) crystal plane, and the nanowires define an angle of 35.3 degrees with respect to the (100) crystal plane.

24. The nanowire structure as described in claim 21, wherein the crystal plane comprises a (110) crystal plane, and the nanowires define an angle of 54.7 degrees with respect to the (110) crystal plane.

25. The nanowire structure as described in claim 21, wherein the crystal plane comprises a (111) crystal plane, and the nanowires define an angle of 19.4 degrees with respect to the (111) crystal plane.

26. The nanowire structure as described in claim 25, further comprises nanowires perpendicular to the (111) crystal plane.

27. The nanowire structure as described in claim 21, wherein a diameter of the nanowires is in the range from 50 to 250 nanometers.

28. The nanowire structure as described in claim 21, wherein a length of the nanowires is in the range from 10 micrometers to 90 micrometers.

29. The nanowire structure as described in claim 21, wherein the nanowires and the substrate are comprised of the same material.

30. A nanowire structure comprising:
a substrate comprising a surface of predefined crystal orientation;
a plurality of nanowires grown on said surface of said substrate along an epitaxial direction according to said predefined crystal orientation of said surface.

31. The nanowire structure as described in claim 30, wherein said substrate is a silicon wafer selected from the group consisting of a (100) silicon wafer, a (110) silicon wafer and a (111) silicon wafer.

32. The nanowire structure as described in claim 30, wherein said plurality of nanowires are grown epitaxially according to said predefined crystal orientation along a <111> epitaxial direction.
